(19) United States
(12) Patent Application Publication
(10) Pub. No.: US 2010/0264017 A1
(43) Pub. Date: Oct. 21, 2010

(54) METHOD FOR DEPOSITING CERAMIC THIN FILM BY SPUTTERING USING NON-CONDUCTIVE TARGET

(76) Inventors: Sang-Cheol Nam, Seoul (KR); Ho-Young Park, Seoul (KR); Young-Chang Lim, Seoul (KR); Ki-Chang Lee, Seoul (KR); Kyu-Gil Choi, Seoul (KR); Ho-Sung Hwang, Seoul (KR); Gi-Back Park, Gyeonggi-do (KR)

Correspondence Address: EDWARDS ANGELL PALMER & DODGE LLP, P.O. BOX 55874, BOSTON, MA, 02205, US

(21) Appl. No.: 12/670,576

(22) PCT Filed: Jul. 24, 2008
(86) PCT No.: PCT/KR08/04344

§ 371 Date: Jun. 27, 2010

(30) Foreign Application Priority Data
Jul. 25, 2007 (KR) 10-2007-0074794

(51) Int. Cl. C23C 14/34

(52) U.S. Cl. 204/192.15; 204/298.02

(57) ABSTRACT

A method for depositing a ceramic thin film by sputtering is provided to increase deposition rate of the ceramic thin film and to enhance the uniformity of a deposited thin film, which are accomplished by positioning a nonconductive target within a vacuum chamber, and applying an AC/RF power to the target to produce plasma within the chamber, followed by the application of a hybrid power in combination of an AC/RF power and a DC power to the target to proceed a sputtering process inside the vacuum chamber, such that the ceramic thin film is deposited on a substrate placed in the vacuum chamber.

### TECHNICAL FIELD

The present invention relates to a method and an apparatus for depositing a ceramic thin film by sputtering using a non-conductive target. Examples of such a ceramic thin film for which the present invention can be implemented include lithium metal oxide thin films such as LiCoO₂, LiMn₂O₄, LiNiO₂ and so forth, which are used as a cathode for a secondary thin film lithium battery, and CIGS (Cu(In, Ca)Se₂) used as a semiconductor material for a solar cell. In particular, the following description will focus on a method for depositing a LiCoO₂ thin film, the most essential element for a all-solid-state secondary thin film lithium battery, by sputtering using a non-conductive LiCoO₂ target.

### BACKGROUND ART

Although all-solid-state thin film lithium batteries have many advantages, differences in deposition rates of the respective thin films forming such a battery and a poor yield on the batteries because of the (relatively slow) deposition rate of ceramic-based films such as oxides remain as key problems to overcome. A cathode for such a thin film battery is usually in form of a lithium based metal oxide thin film, such as, LiCoO₂, LiMn₂O₄, or LiNiO₂ thin film, which is required not only to facilitate lithium-inter/deintercalation processes in active electrode materials for charging/discharging, but also to have a high drive voltage. The most common method for depositing those cathode materials in thin film form is PVD (Physical Vapor Deposition) such as sputtering.

However, for thin film batteries to have a wider range of commercial uses, it is crucial to quickly deposit a ceramic thin film made of an oxide or nitride, which is a material for the cathode and for a solid electrolyte, at a thickness of 1 micron or greater. In case of LiCoO₂ as noted earlier as one of cathode materials, it is usually deposited slowly by the conventional RF sputtering method. For the mass production, therefore, a high-voltage AC high-frequency power generator based on many chambers or for use in a very large LiCoO₂ target is needed. The LiCoO₂ thin film is sputtered under argon or argon/oxygen atmosphere at the composition ratio of Li:Co:O=1:1:2, and after the deposition process it is crystallized through an annealing process to form a stable state with a reversible structure. Despite the unique structure and electrochemical stability of LiCoO₂, the processing speed and its precision-recall do not yet meet the commercialization requirement.

Therefore, an RF source is advantageous in that it enables sputtering to be carried out using an electric nonconductor as a target, but it is relatively more expensive than a DC power generator (to be described) and demonstrates a slow deposition speed.

By the use of the DC power generator, on the other hand, the device becomes more simplified and easy to operate, but it absolutely requires a conductive target with excellent thermal conductivity.

U.S. Pat. No. 4,931,169 disclosed a magnetron sputtering method, in which dielectrics are deposited on a substrate by superimposing the output voltage of an AC power generator on the DC voltage of a DC power generator at an output corresponding to 5-25% of the output supplied by the DC power generator. Here, a metal such as Al, Si, or Sn is used as a target in consideration of the electrical conductivity and thermal conductivity.

In addition, DE4413378A1 (Patent family No: 10-0269403 in Korea) citing the above patent registration also discloses a magnetron sputtering method, in which an ITO thin film is deposited over a substrate by superimposing an AC power generator on a DC power generator. Here, an ITO having 90% or higher compressibility and 5-10% oxygen deficiency is defined as a target. It is also well known that the electrical conductivity and optical transparency are some of distinguishing properties of the ITO.

Meanwhile, U.S. Pat. Nos. 5,830,336 and 6,039,850 disclosed a lithium sputtering method, in which either an AC potential or a DC potential is applied in a forward direction to a target, and then a reverse potential is applied before termination of the AC or DC potential in a reverse direction opposite to the forward direction. Here, a target is composed of a supporting layer made out of stainless steel, copper, or a copper based alloy, an indium coating applied to the top of the supporting layer metal, and metallic lithium covering the indium coating, in order to provide electroconductive properties.

### DISCLOSURE OF INVENTION

### Technical Problem

The present invention is conceived to solve the aforementioned problems in the prior art. An object of the present invention is to provide a novel deposition method for producing a ceramic thin film at high deposition rate by applying a hybrid power with benefits of both DC power and RF power to a nonconductive sputtering target.

Another object of the present invention is to provide a method for depositing a ceramic thin film having the most desirable composition and crystalline structure through the adjustment of process variables during sputtering.

Still another object of the present invention is to provide a method for increasing deposition rate of ceramic thin films suitable for thin film lithium batteries, thereby ensuring mass productivity for realizing the commercialization of thin film batteries.

### Technical Solution

According to an aspect of the present invention, there is provided a method for depositing a ceramic thin film by sputtering, in which a target made out of a non-conductive material is positioned inside a vacuum chamber, and an AC/RF power is first applied to the target to produce plasma within the chamber, followed by the application of a hybrid power in combination of an AC/RF power and a DC power to proceed a sputtering process within the vacuum chamber, such that a ceramic thin film is deposited on a substrate located within the vacuum chamber.

In an exemplary embodiment, the target is made out of a material selected from the group consisting of LiCoO₂, LiMn₂O₄, LiNiO₂, and CIGS (Cu(In, Ca)Se₂).

Alternatively, the target may be made out of a material selected from the group consisting of LiFePO₄, LiNiVO₄, LiCoMnO₄, LiCo_{1/3}Ni_{1/3}Mn_{1/3}O₂, LiₓV₂O₅, LiₓMoO₃, LiₓWO₃, LiₓTiS₂, LiₓMoS₂ and Li₄Ti₅O₁₂.

Preferably, the target material is prepared by compressed-sintering, and a ceramic thin film having the same composition with the target material is deposited by sputtering.

In an exemplary embodiment of the present invention, the first applied AC/RF power has the same power level with the hybrid power in terms of a sum of AC/RF and DC powers.

Meanwhile, the first applied AC/RF power has a lower power level than the hybrid power in terms of a sum of AC/RF and DC powers.

Preferably, the DC power in the hybrid power should be 30% or more of a sum of AC/RF and DC power level in order to secure uniformity of a deposited film.

In an exemplary embodiment of the present invention, the application of an AC/RF power serves to produce and maintain plasma, and the application of a DC power serves to provide power required for sputtering.

Another aspect of the present invention provides a thin film sputtering device using a nonconductive target, comprising: a vacuum chamber including a stage on which the nonconductive target and a substrate are positioned; an AC power source for supplying an AC power to the target; a DC power source for supplying a DC power to the target; and a matching box for performing impedance matching to synthesize and/or hybridize the AC power with the DC power.

Here, the matching box preferably includes a plurality of input ends for receiving power from the AC power source and from the DC power source independently, and an output end for outputting power to the target.

### ADVANTAGEOUS EFFECTS

The hybrid power in combination of the DC power and the AC/RF power in accordance with the present invention can be advantageously used for the manufacture of thin film batteries through sputtering of a lithium metal oxide-based active cathode material, which particularly contributes to decreasing the thin film deposition processing time and to improving uniformity of the deposited thin film.

With the use of the hybrid power, the AC/RF power can be involved only in the plasma production so a relatively low-price, low-power AC/RF output can be utilized, instead of the conventional high-price, high-power AC/RF output used for the mass production and commercialization of thin film batteries.

In addition, the present invention method makes it possible to induce crystallization of an active cathode material having an influence on the lithium inter/deintercalation properties during the manufacture of lithium metal oxide-based thin film batteries, and to deposit thin films exhibiting satisfactory interface characteristics and chemical stability.

Moreover, compared with the conventional RF sputtering, the present invention sputtering method noticeably improves the sputtering deposition rate for a non-conductive target and the uniformity of the deposited thin film.

### BRIEF DESCRIPTION OF THE DRAWINGS

FIG. 1 shows a schematic view of a sputtering device in which a hybrid power in combination of DC power and AC/RF power can be implemented, in accordance with the present invention;

FIG. 2 graphically shows deposition rate and uniformity of a thin film in relation to a change in applied DC power ratio, provided that a total power is kept at a constant level of 2.5 kW;

FIG. 3 graphically shows deposition thicknesses of a thin film at different positions on a substrate with respect to an increase in applied DC power ratio, provided that a total power is kept at a constant level of 2.5 kW;

FIG. 4 graphically shows deposition rate and uniformity of a thin film in relation to increasing RF power, provided that DC power is kept at a constant level of 2.3 kW;

FIG. 5 graphically shows the charge-discharge efficiency of a thin film battery using a sputter-deposited lithium cobalt oxide thin film obtained by applying a hybrid power to a target under the conditions listed in Table 1;

FIG. 6 shows an XRD pattern before and after an annealing process on a thin film battery using a sputter-deposited lithium cobalt oxide thin film obtained by applying a hybrid power to a target under the conditions listed in Table 1; and

FIG. 7 and FIG. 8 respectively show AFM (Atomic Force Microscopy) images before annealing (i.e., as-deposited, FIG. 7) and after annealing (FIG. 8) of surface morphology for a thin film battery using a sputter-deposited lithium cobalt oxide thin film obtained by applying a hybrid power to a target under the conditions listed in Table 1.

### MODE FOR THE INVENTION

Hereinafter, preferred embodiments of the present invention will be described in detail with reference to the accompanying drawings.

After the inventors have dedicated much efforts to developing a technique for increasing deposition rate that is regarded as the biggest problem in the conventional RF sputtering process on a nonconductive target, they learned that the sputtering deposition rate of a thin film could be increased when an AC/RF power is first applied to a nonconductive target to form plasma within a chamber and then a hybrid power in combination of an AC/RF power and a DC power is applied to the target, such that the applied DC power from a hybrid power supply is used as power for sputtering the plasma in the chamber after all. Another unexpected fact the inventors have discovered that even the uniformity of the deposited thin film got improved by the new technique, compared to that of the deposited thin film done by the conventional sputtering.

Under such a power application scheme, a considerable amount (e.g., 2.5 kW) of AC/RF power was applied first to a target to form plasma within a chamber, and then a reduced amount of AC/RF power and a DC power making up the difference are applied to the target. For example, suppose that a hybrid power in combination of 0.2 kW of RF power+2.3 kW of DC power was applied to a target. In this particular case, 2.3 kW of DC power is eventually supplied to the plasma formed within the chamber as energy necessary for sputtering such that the deposition rate of a thin film and the uniformity of a deposited thin film could be improved.

Alternatively, an AC/RF power which may be small but sufficient, e.g., 0.2 kW, to form plasma within a chamber may be supply first to a target, and then a DC power may be applied to the target additionally while maintaining the application of the AC/RF power at the same amount. For example, suppose that a hybrid power in combination of 0.2 kW of RF power+2.3 kW of DC power was applied to a target. In this case, the additionally applied 2.3 kW of DC power is eventually supplied to the plasma formed within the chamber as energy necessary for sputtering such that the deposition rate of a thin film and the uniformity of a deposited thin film could be improved.

Either way, the deposition rate of a ceramic thin film on a substrate was noticeably improved, compared to the deposition rate in the conventional RF sputtering. Besides, an enhanced uniformity of the deposited thin film, compared to that of the conventional RF sputtering, was surely an unexpected and remarkable outcome.

Although the inventors have not tried the ceramic film deposition under the conditions (to be described) on every single nonconductive target, they conducted the deposition for at least LiCoO₂, LiMn₂O₄, LiNiO₂, CIGS (Cu(In, Ca)Se₂) to get the same results. In the interest of brevity and convenience, the following description will be focused on the film deposition for LiCoO₂ as an example. However, one can expect to get the same effects and advantages by regulating the initially applied AC/RF voltage and the antecedently applied hybrid power composed of RF power and DC power, according to the concept suggested by the present invention and in consideration of different physical properties of targets.

Besides lithium cobalt oxide (LiCoO₂), lithium manganese oxide (LiMn₂O₄), and lithium nickel oxide (LiNiO₂) noted before as the materials most often used for the cathode of a secondary thin film lithium battery, lithium iron phosphate (LiFePO₄), lithium nickel vanadium oxide (LiNiVO₄), lithium cobalt manganese oxide (LiCoMnO₄), lithium cobalt nickel manganese oxide (LiCo_{1/3}Ni_{1/3}Mn_{1/3}O₂), lithium vanadium oxide (LiₓV₂O₅), lithium molybdenum oxide (LiₓMoO₃), lithium tungsten oxide (LiₓWO₃), lithium titanium sulfide (LiₓTiS₂), lithium molybdenum sulfide (LiₓMoS₂), etc., may also be used as materials for the nonconductive target, each being equally deposited in form of a thin film. In addition, other materials such as lithium titanium oxide (Li₄Ti₅O₁₂), lithium nickel vanadium oxide (LiNiVO₄), lithium molybdenum oxide (LiₓMoO₃), lithium tungsten oxide (LiₓWO₃), etc. most often used for the anode of a secondary thin film lithium battery may be used as target materials, each being equally deposited in form of a thin film.

Hereinafter, a preferred embodiment of the present invention will now be explained, taking the formation of a lithium cobalt oxide thin film as an example. It is also to be understood that the embodiment below is not intended to be limiting since the scope of the present invention will be limited only by the appended claims.

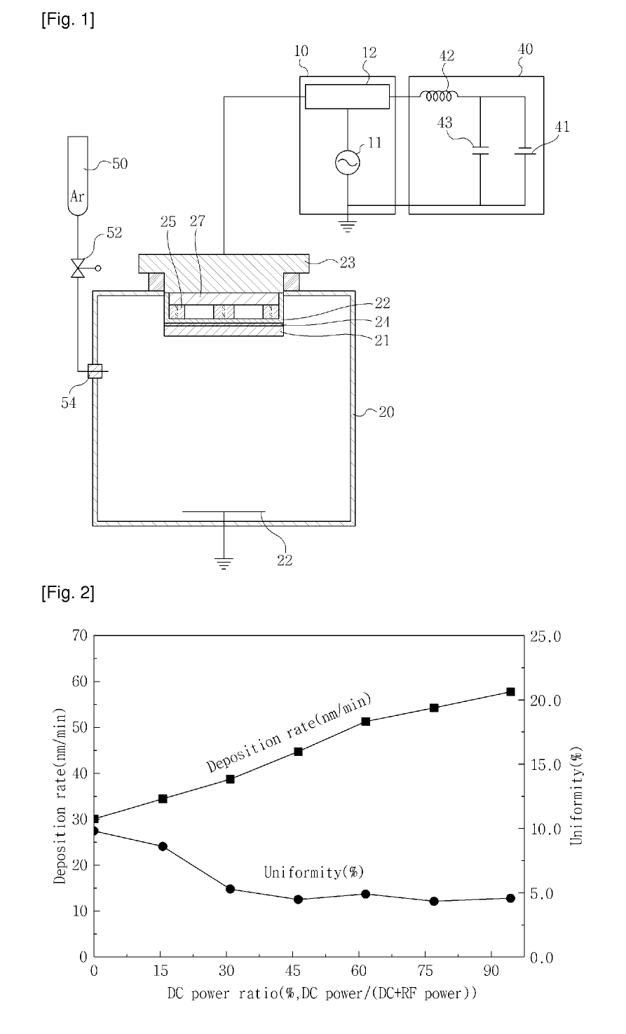

FIG. 1 shows a schematic view of a device for depositing a lithium cobalt oxide thin film by sputtering. A target 21 is prepared by compressed-sintering of lithium cobalt oxide powder in form of a disc with a diameter of 300 mm and a thickness of 5 mm for example. The target 21 is bonded to an indium coating 24 formed on the top surface of a support plate 22 in an upper portion of a vacuum chamber 20. Since methods of mounting a nonconductive target on a wall of a sputtering chamber or magnetron sputtering chamber are already well known in the art, details on such methods will not be provided here. An electrode 23 and the support plate 22 are conductive metals such as copper, copper based alloy, stainless steel, etc., electrically connecting a power supply and the target 21. In a preferred embodiment of the present invention based on the magnetron sputtering method, a yoke 27 is installed underneath the electrode 23, and a plurality of permanent magnets 25 are arranged to have N pole and S pole set alternately between the yoke 27 and the support plate 25. It is also well known in the art that the permanent magnets 25 generate a magnetic field converging plasma to the target 21. An inert gas, Ar, is introduced from a gas tank 50 into the vacuum chamber 20 via a valve 52 and an inlet 54, and functions as atmospheric gas.

Referring to FIG. 1, the vacuum chamber 20 accommodates an AC power source 11 for supplying AC, particularly RF power, a matching box 12 for impedance matching, a stage 22 where a substrate with a thin film deposited thereon is seated, and a target 21 made of a nonconductive material such as lithium cobalt oxide. Hereinafter, the AC power source 11 together with the matching box 12 will be referred to as an AC power supply 10.

The sputtering deposition device in accordance with the present invention further includes a DC power supply 40, a DC power source 41, an inductor 42, and a capacitor 43, in which the DC power source 41 supplies a DC power to the target 21, and the inductor 42 and the capacitor 43 constitute an LC filter to prevent an AC power generated from the AC power source 11 from flowing into the DC power source 41 via a hybridization portion 30.

Depending on the kind of the matching box 12 used, a separate hybridization portion may not be required at all. Nevertheless, it is possible to apply a hybrid power to the target 21 within the vacuum chamber simply by connecting the AC power source 11 and the DC power supply 40 to different positions of the matching box 12. That is, a hybrid power can be generated by connecting the AC power source 11 and the DC power supply 40 to different input ends of the matching box 12 in the sputtering deposition device shown in FIG. 1, while the output end of the matching box 12 is electrically connected to the target 21.

Optionally, special equipment like a DC coupler may be utilized to apply a hybrid power. In this case, the AC power supply 10 and the DC power supply 40 are connected to input ends of the special equipment, and the special equipment is supplied with power from a different path to hybridize power. The hybrid power is then electrically connected to the target 21 through an output end of the special equipment.

The DC power supply 40 including the DC power source 41, the inductor 42, and the capacitor 43 supplies a DC power which is required for sputtering. The AC power source 11 and the matching box 12 supply an AC power which generates and maintains plasma. Depending on the type of the matching box 12 used, the matching box 12 can also synthesize DC and AC power.

Functions and roles of the stage 22, the target 21, and the vacuum chamber 20 during sputtering are already well known in the art and discussed earlier, so details on them will not be provided here. One thing to notice is, however, that a hardmask (not shown) is placed on a substrate (not shown) prior to sputtering and carried into the vacuum chamber 20 where the sputtering process proceeds. In this way, sputtered particles from the target 21 can be deposited on only desired portions of the substrate (not shown). Alternatively, a substrate (not shown) may be carried into the vacuum chamber 20 and then placed on a hardmask (not shown) having already been positioned inside the vacuum chamber 20, such that sputtered particles from the target 21 can be deposited on only desired portions of the substrate (not shown). Getting into further details will not be necessary though because deposition of sputtered particles on only desired portions of a substrate (not shown) by the use of a hardmask (not shown) is already well known in the art.

Another factor to be taken into consideration about a deposited thin film is the uniformity. The uniformity closer to 0 means the thickness of a deposited thin film over the entire substrate is almost even.

In a preferred embodiment of the present invention, a hybrid power supply simultaneously applies a DC power and an AC/RF power to the 4-inch size target 21 made of a nonconductive material like LiCoO₂ within the vacuum chamber to produce plasma therein, such that a ceramic thin film made of an active cathode material LiCoO₂ is deposited by sputtering over a thin film battery substrate placed on the stage 22. It is believed that the AC/RF power functions to produce and maintain plasma, while the DC power provides a sputtering power.

The deposition rate of the thusly obtained LiCoO₂ thin film and the deposition rate of LiCoO₂ thin film obtained through a conventional AC/RF power were compared to each other in Table 1 below. Under the same condition of sputtering power (300 W) for plasma production, the use of a hybrid power in accordance with the present invention demonstrated much faster deposition rate by about 60% than that of the conventional AC/RF power.

TABLE 1

Sputtering power

| | RF | DC + RF hybrid |
|---|---|---|
| Applied voltage (W) | 300 | 280 + 20 |
| Deposition rate (nm/min) | 25 | 40 |

FIG. 2 shows deposition rate in relation to uniformity of a thin film under a given process variable, in which a hybrid power, i.e., a variable RF (13.56 MHz) power ranging from 0.2 to 2.5 kW and a variable DC power ranging from 0 to 2.3 kW, was applied simultaneously to a LiCoO₂ disc target having a diameter of 300 mm and a thickness of 5 mm to deposit a LiCoO₂ thin film on a substrate. Here, the pressure inside the vacuum chamber was set to 0.8 Pa.

Thickness of the thin film was measured by averaging thicknesses of the sample at a designated diagonal distance from the center of a square shape substrate. As can be seen from FIG. 2, when only a 100% RF power (2.5 kW) was applied the deposition rate was about 30 nm/min, but when a hybrid power in combination of an RF power of 0.2 kW and a DC power of 2.3 kW (DC power ratio: 92%, and the total applied power was fixed at 2.5 kW) was applied the deposition rate was increased up to about 58 nm/min (y-axis on the left-hand side). Compared to the conventional sputtering deposition method using the RF power only, the present invention method increased the deposition rate of a thin film as nearly as twice. In fact, the deposition rate increases linearly in proportion to an increase in the DC power ratio. Similarly, the uniformity was about 10% when the RF power only was applied (y-axis on the right-hand side), but it gradually decreased as the DC power ratio increased. For example, when the DC power ratio exceeded 30% the uniformity was lowered below 5% and stayed below 5% even if the DC power ratio was increased. From these observations, the inventors obtained unexpected results that the use of a hybrid power incorporating a DC power, unlike the use of the 100% RF power (DC power ratio: 0%), not only brought a noticeable increase in the deposition rate compared to the deposition rate (30 nm/min) in the comparative example, but also enhanced the uniformity of a deposited thin film. To be short, the deposition rate increases in proportion to the DC power ratio, while the uniformity of a deposited thin film does not increase until the DC power ratio out of a hybrid power used is at least 30% or more. The fact that the uniformity of a deposited thin film can be enhanced with an increase in the DC power ratio out of a hybrid power was a totally unexpected result. This result came as a big surprise especially because the stage was not rotated at all in this embodiment. In relation to this, when permanent magnets installed behind the target rotate, an improvement in the uniformity of a deposited thin film was even more noticeable (not shown).

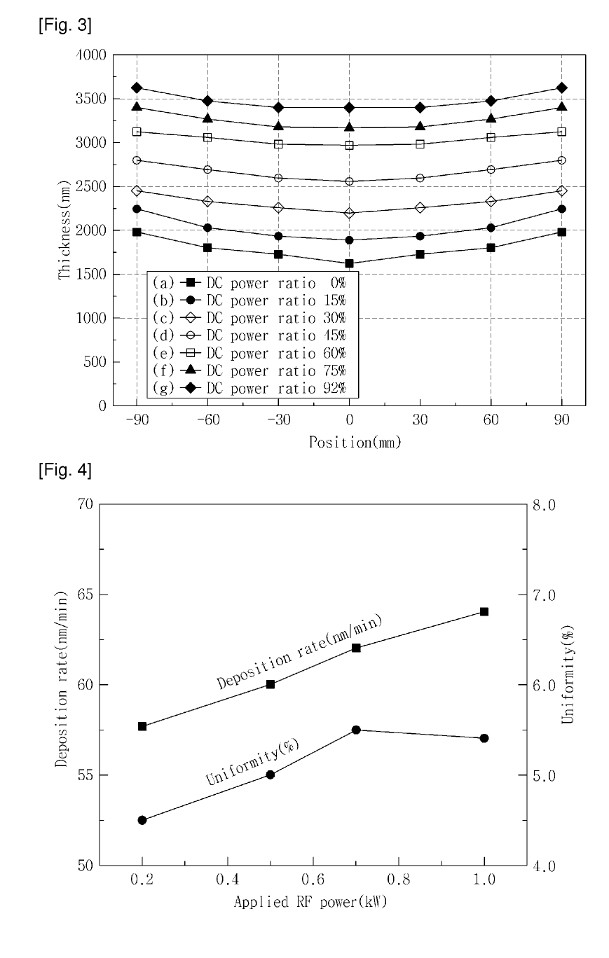

FIG. 3 graphically shows deposition thickness of a thin film (Y-axis) at different positions on a substrate (X-axis) with respect to an increase in applied DC power ratio, provided that a total hybrid power in combination of DC and RF power is kept at a constant level of 2.5 kW, in which (a) illustrates a case where only an RF power of 2.5 kW is applied (as in the conventional method: comparative example); (b) illustrates a case where a DC power ratio was increased up to 15% out of a fixed total power of 2.5 kW; (c) illustrates a case where a DC power ratio was increased up to 30% out of a fixed total power of 2.5 kW; (d) illustrates a case where a DC power ratio was increased up to 45% out of a fixed total power of 2.5 kW; (e) illustrates a case where a DC power ratio was increased up to 60% out of a fixed total power of 2.5 kW; (f) illustrates a case where a DC power ratio was increased up to 75% out of a fixed total power of 2.5 kW; and (g) illustrates a case where a DC power ratio was increased up to 92% out of a fixed total power of 2.5 kW. Each sample was deposited for a fixed period of time, 60 minutes, on a substrate and film thicknesses at different positions of the substrate were measured. As can be seen from the graph in FIG. 2, not only the deposition thickness was linearly increased, but also the uniformity of a thin film at a given position was gradually improved, compared with the case of applying only the RF power.

FIG. 4 graphically shows a change in deposition rate (Y-axis on the left-hand side) and uniformity (Y-axis on the right-hand side) with respect to an increase in RF power (X-axis), provided that the applied DC power is kept at a constant level of 2.3 kW. As can be seen from FIG. 4, the deposition rate was gradually increased, but its obtained values of the deposition rate are substantially low compared to such an increase in the DC power ratio as in FIG. 2. In particular, an increase in the RF power turned out to be disadvantageous in that the uniformity increased up to 5% or higher. From these observations, therefore, one may draw a result from FIG. 4 that an increase in the relative RF power ratio to a fixed hybrid power level failed to bring significant changes in the uniformity of a deposited thin film, but rather impaired the uniformity somewhat by slightly increasing the value of the uniformity.

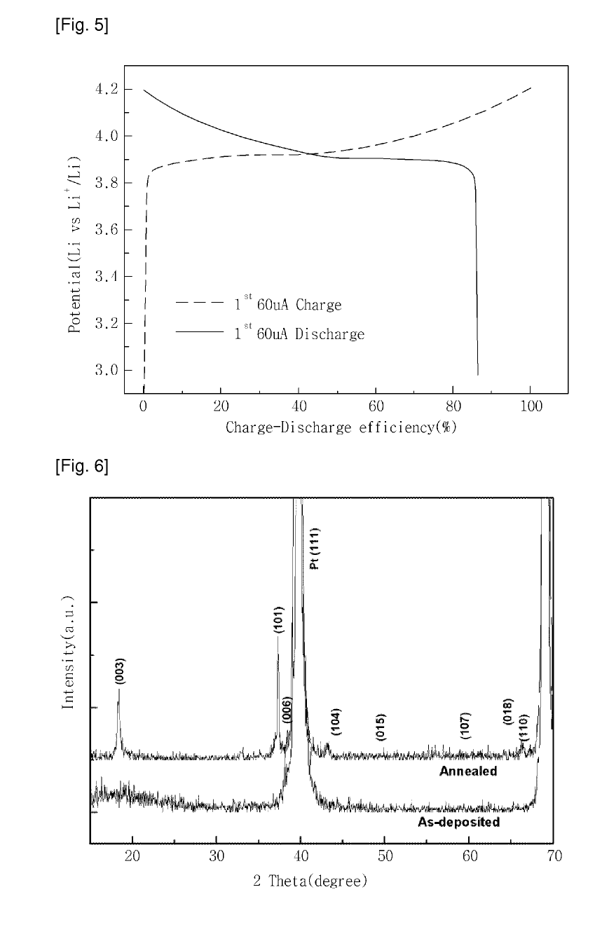

FIG. 5 graphically shows the charge-discharge efficiency of a thin film battery using a sputter-deposited lithium cobalt oxide thin film obtained by applying a hybrid power to a target under the conditions listed in Table 1. According to FIG. 5, the thin film battery having a sputter-deposited lithium cobalt oxide thin film obtained through the application of a hybrid power of the present invention demonstrates the charge-discharge efficiency as high as 90%, which is at least equal to or better than the charge-discharge efficiency of a thin film battery having a lithium cobalt oxide thin film deposited through the application of a conventional AC/RF power. This implies that the deposition rate is fast and the charge-discharge properties are neither inferior to others.

FIG. 6 shows an XRD pattern before and after an annealing process on a thin film battery using a sputter-deposited lithium cobalt oxide thin film obtained by applying a hybrid power to a target under the conditions listed in Table 1. The XRD pattern is used as a basis for finding out the degree of crystallization. In order to enable the performance of specific functions of a battery through the excellent reversibility of lithium intercalation and deintercalation during the charge-discharge process, a portion indicated by reference numeral (101) should have a relatively greater intensity than others. In general, when a lithium cobalt oxide exists in form of a cathode thin film, a crystal face of the portion (101) first adapts alignment. Comparing the graphs before and after annealing, one can see that the portion 101 has a relatively higher intensity than a portion (003), which means that the portion (101) has better crystallization.

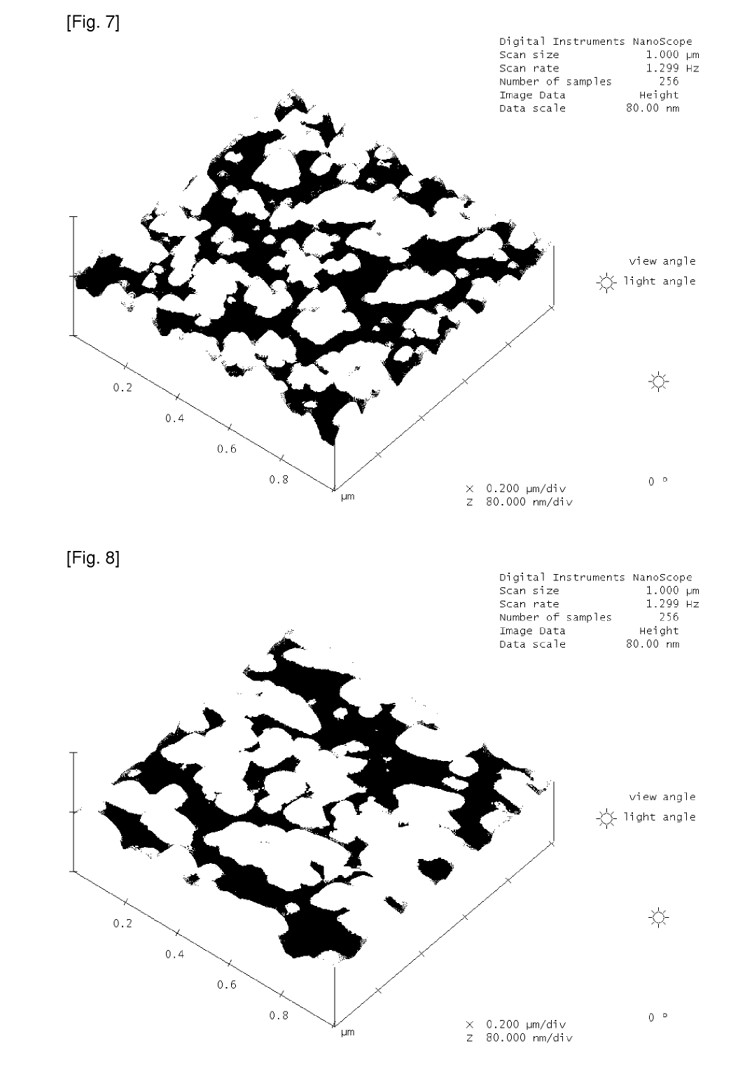

FIG. 7 and FIG. 8 respectively show AFM (Atomic Force Microscopy) images before annealing (i.e., as-deposited, FIG. 7) and after annealing (FIG. 8) of surface morphology for a thin film battery using a sputter-deposited lithium cobalt oxide thin film obtained by applying a hybrid power to a target under the conditions listed in Table 1. An RMS value representing the surface roughness of a thin film measured through AFM assay was reduced from 84.1 before annealing to 66.6 after annealing. These results show that the surface quality of the sputter-deposited lithium cobalt oxide thin film obtained through the application of a hybrid power is as good as that of a sputter-deposited lithium cobalt oxide thin film obtained through the application of a conventional AC-RF power.

Table 2 below shows the results of ICP-AES (Inductively coupled plasma-Atomic emission spectroscopy) conducted to check chemical composition of a sputter-deposited lithium cobalt oxide (LiCoO₂) thin film that is obtained by applying a hybrid power to a target under the conditions listed in Table 1. In particular, Table 2 shows the molar ratio of Li and Co atoms in the lithium cobalt oxide thin film (LiCoO₂) before and after annealing. Provided that a lithium cobalt oxide (LiCoO₂) is sputter-deposited by a DC+AC/RF power, the molar ratio of lithium (Li) and cobalt (Co) in the lithium cobalt oxide thin film (LiCoO₂) before and after annealing turned out to be 1.072:1 and 1.087:1, respectively, which are very close to 1;1. This indicates that the lithium cobalt oxide thin film is chemically stable enough to be used as an cathode for a thin film battery.

TABLE 2

Molar ratio

| | Li | Co |
|---|---|---|
| as-deposited | 1.072 | 1 |
| (before annealing) | | |
| After annealing | 1.087 | 1 |

While the present invention has been illustrated and described in connection with the accompanying drawings and the preferred embodiments, the present invention is not limited thereto and is defined by the appended claims. Therefore, it will be understood by those skilled in the art that various modifications and changes can be made thereto without departing from the spirit and scope of the invention defined by the appended claims.

1. A method for depositing a ceramic thin film by sputtering, in which a target made out of a nonconductive material is positioned inside a vacuum chamber, and an AC/RF power is first applied to the target to produce plasma within the chamber, followed by the application of a hybrid power in combination of an AC/RF power and a DC power to proceed a sputtering process within the vacuum chamber, such that a ceramic thin film is deposited on a substrate located within the vacuum chamber.

2. The method of claim 1, wherein the target is made out of a material selected from the group consisting of LiCoO₂, LiMn₂O₄, LiNiO₂, and CIGS (Cu(In, Ca)Se₂).

3. The method of claim 1, wherein the target is made out of a material selected from the group consisting of LiFePO₄, LiNiVO₄, LiCoMnO₄, LiCo_{1/3}Ni_{1/3}Mn_{1/3}O₂, LiₓV₂O₅, LiₓMoO₃, LiₓWO₃, LiₓTiS₂, LiₓMoS₂ and Li₄Ti₅O₁₂.

4. The method of one of claims 1 through 3, wherein the target material is prepared by compressed-sintering, and a ceramic thin film having the same composition with the target material is deposited by sputtering.

5. The method of one of claims 1 through 3, wherein the first applied AC/RF power has the same power level with the hybrid power in terms of a sum of AC/RF and DC powers.

6. The method of one of claims 1 through 3, wherein the first applied AC/RF power has a lower power level than the hybrid power in terms of a sum of AC/RF and DC powers.

7. The method of one of claims 1 through 3, wherein the DC power in the hybrid power corresponds to 30% or more of a sum of AC/RF and DC power level.

8. The method of one of claims 1 through 3, wherein the application of an AC/RF power serves to produce and maintain plasma, and the application of a DC power serves to provide power required for sputtering.

9. A thin film sputtering device using a nonconductive target, comprising:
a vacuum chamber including a stage on which the nonconductive target and a substrate are positioned;
an AC power source for supplying an AC power to the target;
a DC power source for supplying a DC power to the target; and
a matching box for performing impedance matching to synthesize and/or hybridize the AC power with the DC power.

10. The device of claim 9, wherein the matching box includes a plurality of input ends for receiving power from the AC power source and from the DC power source independently, and an output end for outputting power to the target.
